(19) United States
(12) Patent Application Publication
(10) Pub. No.: US 2013/0189821 A1
(43) Pub. Date: Jul. 25, 2013

(54) METHODS FOR FABRICATING SEMICONDUCTOR DEVICES WITH REDUCED DAMAGE TO SHALLOW TRENCH ISOLATION (STI) REGIONS

(71) Applicants: Hans-Jürgen Thees, Dresden (DE); Boris Bayha, Dresden (DE)

(72) Inventors: Hans-Jürgen Thees, Dresden (DE); Boris Bayha, Dresden (DE)

(73) Assignee: GLOBALFOUNDRIES INC., Grand Cayman (KY)

(21) Appl. No.: 13/356,326

(22) Filed: Jan. 23, 2012

(51) Int. Cl. H01L 21/336

(52) U.S. Cl. 438/296; 257/E21.409

(57) ABSTRACT

Methods for fabricating semiconductor devices are provided. In an embodiment, a method of fabricating a semiconductor device on a semiconductor substrate includes selectively implanting dopant ions to form implants in the semiconductor substrate. Trenches are formed in the semiconductor substrate and the trenches are filled with an isolation material. An upper surface of the isolation material is established substantially coplanar with the semiconductor substrate. In the method, the implants and the isolation material are then simultaneously annealed.

### TECHNICAL FIELD

The present disclosure generally relates to methods for fabricating semiconductor devices, and more particularly relates to methods for fabricating semiconductor devices with reduced damage to shallow trench isolation (STI) regions.

### BACKGROUND

As miniaturization of elements of an integrated circuit semiconductor device drives the industry, not only must critical dimensions of elements shrink, but also vertical variation or “topography” must be minimized in order to increase lithography and etch process windows and, ultimately, the yield of integrated circuits.

Conventional shallow trench isolation (STI) fabrication techniques include forming a pad oxide on an upper surface of a semiconductor substrate, forming a nitride, e.g., silicon nitride, polish stop layer thereon, etching the stop layer and semiconductor substrate to form a trench and active regions in the semiconductor substrate, forming a thermal oxide liner in the trench and then filling the trench with isolation material, such as silicon oxide, forming an overburden on the nitride polish stop layer. Planarization is then implemented, as by conducting chemical mechanical polishing (CMP). During subsequent processing, the nitride layer is removed along with the pad oxide followed by doping of active areas, which typically involve masking, ion implantation, and cleaning steps. During such cleaning steps, the top corners of the isolation material are isotropically removed leaving voids or “divots” in top surface of the isolation material. The resulting vertical variation makes the proper structure and encapsulation of any gate extending across an STI region difficult, particularly as critical dimensions shrink.

Also, conventional STI fabrication techniques face difficulty in filling the STI trenches without voids, gaps or other irregularities. Therefore, spin-on glass (SOG) or other oxide materials are used. However, these oxide materials have high wet etch rates. In order to reduce their etch rates, high temperature, e.g., 950° C.-1150° C.), and long duration anneals are added during the STI formation process, leading inevitably to a shrinkage of the film and a densification of the oxide. A drawback of this approach is that increased overlay errors can happen if wafers are subjected to the mechanical stress of such annealed films.

Accordingly, it is desirable to provide methods for fabricating semiconductor devices with reduced damage to STI regions. In addition, it is desirable to provide methods for fabricating semiconductor devices which avoid use of high temperature anneals for densifying the isolation material. Furthermore, other desirable features and characteristics will become apparent from the subsequent detailed description and the appended claims, taken in conjunction with the accompanying drawings and the foregoing technical field and background.

### BRIEF SUMMARY

Methods are provided for fabricating a semiconductor device. In accordance with one embodiment, the semiconductor device is fabricated on a semiconductor substrate. The method includes selectively implanting dopant ions to form implants in the semiconductor substrate. Trenches are formed in the semiconductor substrate, and the trenches are filled with an isolation material. An upper surface of the isolation material is established substantially coplanar with the semiconductor substrate. In the method, the implants and the isolation material are then simultaneously annealed.

In another embodiment, a method is provided for fabricating a semiconductor device on a semiconductor substrate. In the method, a planarization stop layer is deposited overlying the semiconductor substrate. Trenches are formed in the semiconductor substrate, and an isolation material is deposited in the trenches. The method planarizes the isolation material to the planarization stop layer. A uniform portion of the isolation material is then removed to establish an upper surface of the isolation material non-intersecting with the semiconductor substrate.

In accordance with another embodiment, a method for fabricating a semiconductor device includes providing a semiconductor substrate with a pad oxide layer overlying a semiconductor layer. An implant mask is formed over the semiconductor substrate, and dopant ions are selectively implanted to form implants in the semiconductor substrate. The implant mask is removed and a planarization stop layer is deposited on the semiconductor substrate. The method etches the planarization stop layer and the semiconductor substrate to form trenches in the semiconductor substrate. An isolation material is then deposited in the trenches and is planarized to the planarization stop layer. In the method, a dry deglazing process is performed with hydrofluoric (HF) acid vapor to establish an upper surface of the isolation material non-intersecting with the semiconductor substrate and to remove residual oxide from the planarization stop layer. The planarization stop layer is removed from the semiconductor substrate. The implants and the isolation material are simultaneously annealed at a temperature of about 650° C. to about 1050° C. in an ambient atmosphere of oxygen or nitrogen. After annealing the implants and the isolation material, the pad oxide layer is removed from the semiconductor substrate and a gate insulator layer is formed on the semiconductor layer.

### BRIEF DESCRIPTION OF THE DRAWINGS

Embodiments of the transistor and methods of fabrication will hereinafter be described in conjunction with the following drawing figures, wherein like numerals denote like elements, and wherein:

FIGS. 1-10 illustrate, in cross section, method steps for fabricating a semiconductor device in accordance with various embodiments herein.

### DETAILED DESCRIPTION

The following detailed description is merely exemplary in nature and is not intended to limit the fabrication methods, applications or uses of the transistor. Furthermore, there is no intention to be bound by any expressed or implied theory presented in the preceding technical field, background or brief summary, or in the following detailed description.

It is contemplated herein that vertical variation of the isolation material forming STI regions can be reduced or eliminated through planarization of the isolation material followed by removal of a uniform amount of the isolation material, such as by a dry deglazing process, and maintaining this condition by elimination of subsequent damage by implantation and cleaning processes. Further, it is contemplated that a single low temperature anneal can be used to simultaneously activate implant areas and to reduce the etch rate of the isolation material forming the STI regions.

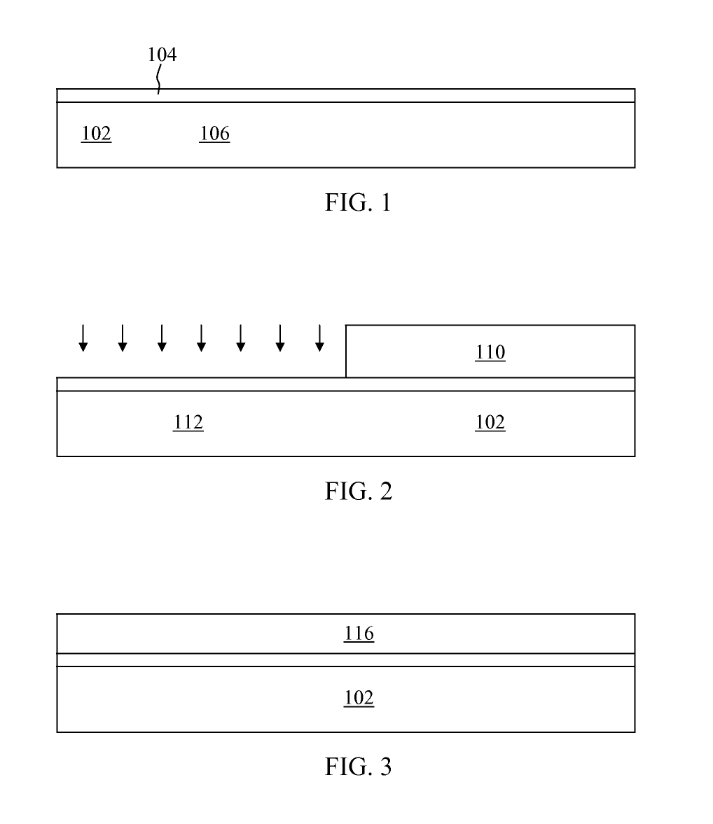

In accordance with the various embodiments herein, a method for fabricating a semiconductor device results in reduced vertical variation in the isolation material forming the device's STI regions. In various embodiments herein, the method includes a single annealing step to simultaneously anneal both the isolation material forming the STI and the well implants. FIGS. 1-10 illustrate, in cross section, a semiconductor device and method steps for fabricating such a semiconductor device in accordance with various embodiments herein. Various steps in the fabrication of semiconductor devices are well known and so, in the interest of brevity, many conventional steps will only be mentioned briefly herein or will be omitted entirely without providing the well known process details.

Turning now to FIG. 1, in an exemplary embodiment, the process of fabricating a semiconductor device begins by providing a semiconductor substrate 102 with a pad oxide layer 104 overlying a semiconductor layer 106. Alignment marks for implants may also be formed. The semiconductor layer 106 may be bulk silicon or a silicon on insulator (SOI) wafer. The silicon on insulator (SOI) wafer includes a silicon-containing material layer overlying a silicon oxide layer. In certain embodiments, the semiconductor substrate may be considered to include only the semiconductor layer 106. While the semiconductor layer 106 is preferably a silicon material, the term “silicon material” is used herein to encompass the relatively pure silicon materials typically used in the semiconductor industry as well as silicon admixed with other elements. Alternatively, the semiconductor layer 106 can be realized as germanium, gallium arsenide, and the like.

As shown in FIG. 2, an implant mask 110 is formed over the semiconductor substrate 102 and dopant ions are selectively implanted to form implants 112 in the semiconductor substrate 102. As is well understood, this process often includes a series of masks and implant processes to create the desired body or well implants 112 from the implantation of N-type ions, such as phosphorous or arsenic ions, and P-type ions, such as boron ions, to achieve a desired dopant profile for the body regions (or well regions) of subsequently formed transistor structures.

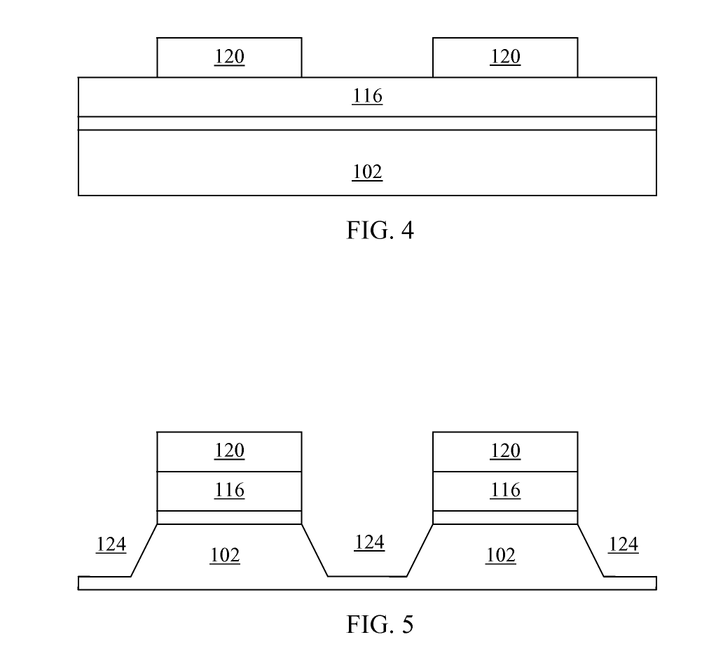

In FIG. 3, the implant mask 110 is removed through a conventional strip/clean sequence. Then, a planarization stop layer 116 is deposited on the semiconductor substrate 102. As described below, the planarization stop layer 116 also serves as a deglazing mask. In an exemplary embodiment, the planarization stop layer 116 is a pad nitride layer which is deposited by chemical vapor deposition (CVD), though the planarization stop layer 116 may be formed from any etchable material that can both serve as a planarization stop and as a deglazing mask.

In FIG. 4, a masking material, such as resist, is patterned over the planarization stop layer 116 to form etch masks 120 in accordance with well known active area lithography processes. The planarization stop layer 116 and semiconductor substrate 102 are etched to form trenches 124 in the semiconductor layer 106 as shown in FIG. 5.

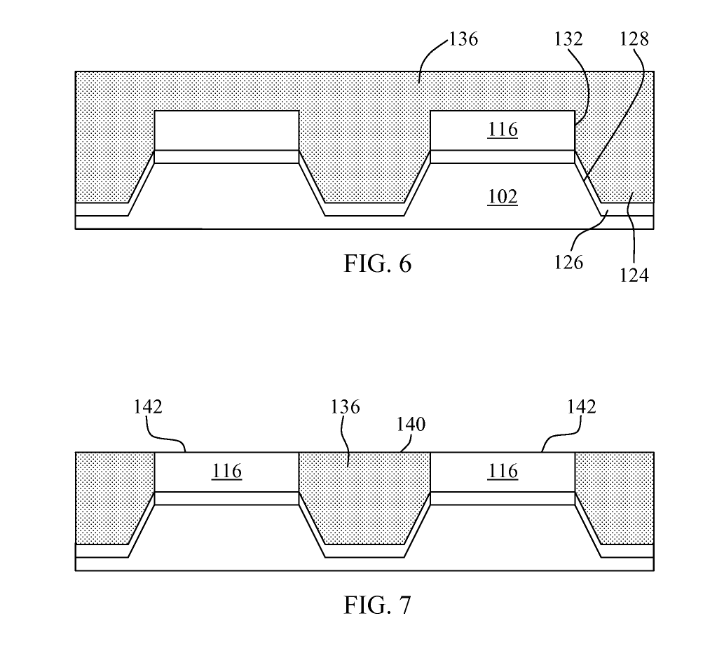

As illustrated in FIG. 6, after etching the trenches 124, the etch masks 120 are removed, such as through a resist strip process. A liner 126 may be formed on the exposed silicon surface 128 of the trenches 124 and (although not illustrated) along the surface 132 of the planarization stop layer 116. For example, the liner 126 may be formed by an oxidation process that results in forming a silicon oxide liner 126 along the surface 128 of the trenches 124 and a silicon oxynitride liner (not shown) along the surface 132 of the planarization stop layer 116. Alternatively, a CVD process can be used to form an oxide or nitride liner 126 overlying the trenches 124 and the planarization stop layer 116.

FIG. 6 further illustrates the deposition of an isolation material 136 in the trenches 124 and overlying the planarization stop layer 116. An exemplary isolation material 136 is a dielectric material, such as silicon dioxide or other field oxide, applied by a spin-coating process. In FIG. 7, the isolation material 136 is planarized to the planarization stop layer 116, i.e., the isolation material 136 is polished until the surface 140 of the isolation material 136 is substantially coplanar with the surface 142 of the planarization stop layer 116. An exemplary process is chemical-mechanical planarization (CMP) using an abrasive and corrosive chemical slurry.

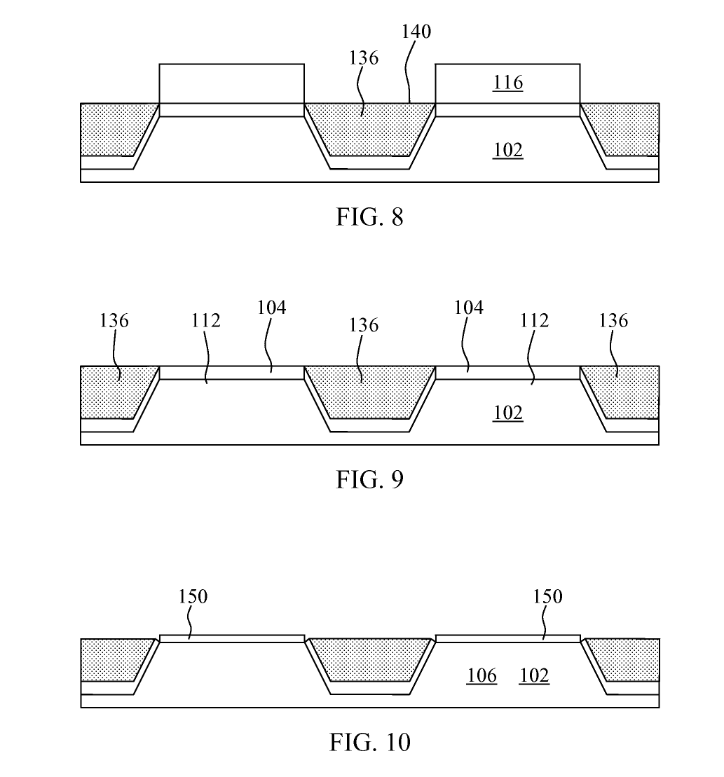

After the isolation material 136 is planarized, a deglazing process is used to remove a desired height/portion of the isolation material 136 to reestablish the surface 140 of the isolation material 136 at a desired step height as shown in FIG. 8. In exemplary embodiments, the surface 140 is substantially coplanar with the semiconductor substrate 102, i.e., the step height of the isolation material 136 over the semiconductor substrate 102 is zero. In exemplary embodiments, a dry deglazing process using hydrofluoric acid vapor removes the isolation material 136 at a uniform depth such that the surface 140 remains planar. The surface 140 is non-intersecting with the semiconductor substrate 102, i.e., it is substantially coplanar with, or parallel to, the surface of the semiconductor substrate 102. After deglazing, the isolation material 136 is substantially divot-free and has no vertical variation. Further, the deglazing process removes any residual oxide on the planarization stop layer 116. Alternatives to the dry deglazing process include performing the deglaze process using a wet etch process, such as with HF acid, or a dry back etch process (isotropic or anisotropic plasma etch process).

As shown in FIG. 9, the planarization stop layer 116 is removed from the semiconductor substrate 102. For a PFET, a SiGe channel may be formed (not shown) in the conventional manner. Then implants and the isolation material are simultaneously annealed at a low to medium temperature, such as about 650° C. to about 1050° C., or about 650° C. to about 950° C., and in an ambient atmosphere of oxygen or nitrogen. The anneal activates the implants 112 and reduces the etch rate of the isolation material 136 and can be done by any known method such as conventional furnace anneals, rapid thermal anneals or laser anneals. The low to medium anneal process can be combined with a rapid thermal anneal or laser anneal to achieve dopant activation in the implants. In fact, the process herein provides for a high degree of freedom regarding the choice of anneal process because, unlike conventional methods, high temperatures and long anneal durations are not necessary. In conventional methods, high temperatures and long anneal durations are necessary to harden the isolation material to provide it with a very low etch rate so that it can withstand the conventional process's multiple implant layer cleans/etches. Because the isolation material need not endure multiple cleans in the methods herein, the isolation material does not require the high temperature/long duration anneal processes of the conventional method.

After the anneal, the pad oxide layer 104 and any oxides formed during the anneal are removed from the semiconductor substrate 102, and a gate insulator layer 150 is formed on the semiconductor layer 106 of the semiconductor substrate 102 as illustrated in FIG. 10. In an exemplary process, an appropriate wet etch and standard gate insulator cleaning step are used to remove the oxide. While the wet etch process may be the same as wet etch processes used in conventional methods, it is the only wet etch process that the isolation material endures. In conventional methods, multiple wet etches remove so much isolation material that a 20 nm to 30 nm positive STI step height (measured when pad nitride is removed) must be used to result in a STI surface that is relatively even with the substrate surface before gate oxide formation. In conventional methods, the positive height of the isolation material is subject to wet etch attack from top and from the side resulting in divots. Use of multiple wet etches is herein avoided. The gate insulator layer 150 may be formed by CVD or thermal oxidation.

Additional processing forming gate structures and transistor structures and well known final process steps (e.g., back end of line (BEOL) process steps) may then be performed. It should be understood that various steps and structures may be utilized in further processing, and the subject matter described herein is not limited to any particular number, combination, or arrangement of steps or structures.

To briefly summarize, the fabrication methods described herein result in semiconductor devices having shallow trench isolation (STI) regions with planar surfaces and uniform step height, and without divots or other structural damage typically caused by wet etching or implant damage and resulting in vertical variation. Further, with a single low to medium temperature anneal process that simultaneously anneals both the implants and the isolation material, the total thermal budget experienced by the wafer is reduced. There is less wafer stress and a better overlay performance is possible.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method of fabricating a semiconductor device on a semiconductor substrate, the method comprising:
selectively implanting dopant ions to form implants in the semiconductor substrate;
forming trenches in the semiconductor substrate;
filling the trenches with an isolation material;
establishing an upper surface of the isolation material substantially coplanar with the semiconductor substrate; and
simultaneously annealing the implants and the isolation material.

2. The method of claim 1 wherein forming the trenches in the semiconductor substrate, filling the trenches with the isolation material, and establishing the upper surface of the isolation material substantially coplanar with the semiconductor substrate comprises:
depositing a planarization stop layer on the semiconductor substrate;
etching the planarization stop layer and the semiconductor substrate to form the trenches in the semiconductor substrate;
depositing the isolation material in the trenches;
planarizing the isolation material to the planarization stop layer; and
performing a dry deglazing process to establish the upper surface of the isolation material substantially coplanar with the semiconductor substrate.

3. The method of claim 2 wherein depositing the planarization stop layer on the semiconductor substrate comprises performing chemical vapor deposition (CVD) to form a pad nitride layer on the semiconductor substrate.

4. The method of claim 2 wherein performing the dry deglazing process comprises removing residual oxide from the planarization stop layer.

5. The method of claim 1 wherein forming the trenches in the semiconductor substrate, filling the trenches with the isolation material, and establishing the upper surface of the isolation material substantially coplanar with the semiconductor substrate comprises:
depositing a planarization stop layer on the semiconductor substrate;
etching the planarization stop layer and the semiconductor substrate to form the trenches in the semiconductor substrate;
depositing the isolation material in the trenches;
planarizing the isolation material to the planarization stop layer; and
performing a deglazing process to establish the upper surface of the isolation material substantially coplanar with the semiconductor substrate, wherein the deglazing process is selected from a group comprising a hydrofluoric (HF) acid wet etch, an isotropic dry plasma etch, or a anisotropic dry plasma etch.

6. The method of claim 1 wherein simultaneously annealing the implants and the isolation material comprises simultaneously annealing the implants and the isolation material at a temperature of about 650° C. to about 1050° C. in an ambient atmosphere comprised of oxygen or nitrogen.

7. The method of claim 1 further comprising:
providing the semiconductor substrate with a pad oxide layer overlying a semiconductor layer; and
after simultaneously annealing the implants and the isolation material, removing the pad oxide layer from the semiconductor substrate and forming a gate insulator layer on the semiconductor layer.

8. The method of claim 1 further comprising:
forming an implant mask over the semiconductor substrate before selectively implanting dopant ions; and
removing the implant mask after selectively implanting dopant ions.

9. The method of claim 1 wherein establishing the upper surface of the isolation material substantially coplanar with the semiconductor substrate comprises:
planarizing the isolation material; and
removing a uniform amount of the isolation material to establish the upper surface of the isolation material substantially coplanar with the semiconductor substrate.

10. A method of fabricating a semiconductor device on a semiconductor substrate, the method comprising:
depositing a planarization stop layer overlying the semiconductor substrate;
forming trenches in the semiconductor substrate;
depositing an isolation material in the trenches;
planarizing the isolation material to the planarization stop layer; and
removing a uniform portion of the isolation material to establish an upper surface of the isolation material non-intersecting with the semiconductor substrate.

11. The method of claim 10 further comprising providing the semiconductor substrate with a pad oxide layer overlying a semiconductor layer.

12. The method of claim 11 further comprising, after removing the uniform portion of the isolation material, removing the pad oxide layer from the semiconductor substrate and forming a gate insulator layer on the semiconductor layer.

13. The method of claim 10 further comprising:
forming an implant mask over the semiconductor substrate;
selectively implanting dopant ions to form well implants in the semiconductor substrate; and
removing the implant mask.

14. The method of claim 13 further comprising simultaneously annealing the well implants and the isolation material at a temperature of about 950° C. to about 1050° C. in an ambient atmosphere comprised of oxygen or nitrogen.

15. The method of claim 10 wherein depositing the planarization stop layer over the semiconductor substrate comprises performing chemical vapor deposition (CVD) to form a pad nitride layer over the semiconductor substrate.

16. The method of claim 10 wherein forming trenches comprises:
forming an etch mask over a surface of the planarization stop layer;
etching the planarization stop layer and the semiconductor substrate to form the trenches; and
removing the etch mask.

17. The method of claim 10 further comprising removing the planarization stop layer after removing the uniform portion of the isolation material.

18. The method of claim 10 further comprising forming a liner in the trenches before depositing the isolation material.

19. The method of claim 10 wherein removing the uniform portion of the isolation material to establish the upper surface of the isolation material non-intersecting with the semiconductor substrate comprises performing a dry deglazing process with hydrofluoric (HF) acid vapor and removing residual oxide from the planarization stop layer

20. A method of fabricating a semiconductor device, the method comprising:
providing a semiconductor substrate with a pad oxide layer overlying a semiconductor layer;
forming an implant mask over the semiconductor substrate;
selectively implanting dopant ions to form implants in the semiconductor substrate;
removing the implant mask;
depositing a planarization stop layer on the semiconductor substrate;
etching the planarization stop layer and the semiconductor substrate to form trenches in the semiconductor substrate;
depositing an isolation material in the trenches;
planarizing the isolation material to the planarization stop layer;
performing a dry deglazing process with hydrofluoric (HF) acid vapor to establish an upper surface of the isolation material non-intersecting with the semiconductor substrate and to remove residual oxide from the planarization stop layer;
removing the planarization stop layer from the semiconductor substrate;
simultaneously annealing the implants and the isolation material at a temperature of about 650° C. to about 1050° C. in an ambient atmosphere comprised of oxygen or nitrogen; and
removing the pad oxide layer from the semiconductor substrate and forming a gate insulator layer on the semiconductor layer after annealing the implants and the isolation material.
